(19) United States
(12) Patent Application Publication
(10) Pub. No.: US 2003/0234436 A1
(43) Pub. Date: Dec. 25, 2003

(54) Semiconductor device with a spiral inductor and magnetic material

(75) Inventors: Heng-Ming Hsu, Science-Based Industrial Park Hsin-chu (TW); Shyh-Chyi Wong, Tai-chung (TW); Jiong-Guang Su, Science- Based Industrial Park (TW)

Correspondence Address: TUNG & ASSOCIATES, Suite 120, 838 W. Long Lake Road, Bloomfield Hills, MI, 48302, US

(73) Assignee: Taiwan Semiconductor Manufacturing Co., Ltd.

(21) Appl. No.: 10/175,116

(22) Filed: Jun. 19, 2002

(51) Int. Cl. H01L 29/00

(52) U.S. Cl. 257/531

(57) ABSTRACT

A semiconductor device having an inductor including a planar coil portion forming an opening in the center thereof and a core received in the opening and extending above and below the planar coil portion. A first and a second inter-metal dielectric layer, and the inductor further including a first connecting leg including an electrically conductive material. The first connecting leg is connected to the planar coil portion. The planar coil portion is in the first inter-metal dielectric layer and the first connecting leg is in the second inter-metal dielectric layer. The inductor further includes a second connecting leg connected to the planar coil portion, and an electrically conductive bump connected to the second connecting leg.

### FIELD OF THE INVENTION

This invention relates generally to inductor structures, and more particularly to microelectronic or semiconductor devices including a planar spiral inductor with a core.

### BACKGROUND OF THE INVENTION

An inductor is an impedance device typically including a coil, with or without a core, for introducing inductance and to an electronic circuit. Both transformers and inductive reactors are included within the meaning of “inductor.” Various inductors are shaped as coils wrapped on various core materials such as ferrites. The core multiplies the inductance of a given coil by the “permeability” of the core material. The core typically is in the shape of a rod or toroid.

To obtain very high inductance, the coil typically includes many turns. Winding the coil on a closed loop iron or ferrite core can further increase the inductance. To obtain as pure an inductance as possible the DC resistance of the winding should be reduced to a minimum. This can be accomplished by increasing the wire size, which increases the size of the choke. The size of the wire also determines the current handling capability of the choke, because the work done in forcing the current through a resistance is converted into heat and the resistance. Magnetic losses in an iron core also produce some heating which restricts any choke to a certain safe operating current. Coil windings must be insulated from the frame as well as from each other. Thicker insulation, which necessarily makes the choke more bulky, is typically used in applications where there's too high-voltage between the frame in the windings. These losses incurred in the iron core increases as the frequency increases. These inductors store energy in the magnetic field in the coil.

Microelectronic or semiconductor devices are typically fabricated from a semiconductor substrate over which patterned conductor layers are formed and separated by dielectric layers. As the microelectronic arts have advanced, integration levels and functionality levels have increased so that not only conventional microelectronic or semiconductor structures such as transistors, resistors, diodes, capacitors are fabricated in or for use with the semiconductor device, but less conventional structures such as inductors and have also been fabricated in or for use with the semiconductor or microelectronic device. In particular, in semiconductor or microelectronic devices that are intended to be employed with high frequency applications, such as mobile communications it is common to employing inductor structures within the semiconductor or microelectronic devices.

A variety of microelectronic conductor structures having desirable properties including enhanced Q values, have been disclosed in the prior art. For example, U.S. Pat. No. 6,002,161 discloses a semiconductor device including an inductor element which includes a first conductive film pattern of a spiral configuration formed on a major face of the semiconductor substrate. A second conductive film pattern of an insular configuration is electronically connected only to the first conductive film pattern through contact holes formed in the interlayer insulation film and extending in an overlapping relationship with the first conductive film pattern.

U.S. Pat. No. 5,977,854 discloses a LC filter including a substrate having a magnetic and dielectric material. The LC filter includes inductors having two three-dimensional spiral structures arranged so that the magnetic fluxes generated at the insides of the spiral structures are parallel and in mutually reversed directions. Plane plate capacitors are also provided between the two three-dimensional spiral structures.

U.S. Pat. No. 6,287,932 discloses a spiral inductor fabricated from a semiconductor substrate that provides a large inductance while occupying only a small surface area. A magnetic material is provided either above or below the inductor to increase the inductance of the inductor. Magnetic material also acts as a barrier that confines electronic noise generated in the spiral conductor to the area occupied by the spiral inductor. The inductance of a pair of stacked spiral inductors is increased by including a layer of magnetic material between the stacked spiral inductors.

U.S. Pat. No. 4,613,843 discloses a planar magnetic transducer that utilizes thin film technology to form a coil on a ceramic substrates. A relatively powerful magnetic reluctance is positioned adjacent the substrate so a changing magnetic reluctance adjacent to the coil can be detected by a voltage change at the coil. The present invention provides alternatives to an advantages over the prior art.

### SUMMARY OF THE INVENTION

One embodiment that the invention includes a semiconductor device including an inductor having a planar coil portion forming an opening in the center thereof and a core received in the opening and extending above and below the planar coil portion.

Another embodiment of the invention includes a semiconductor device having an inductor, planar coil portion with an opening, and a core including a magnetic material.

Another embodiment of the invention includes a semiconductor device having an inductor with a planar coil portion and an opening therein, a core received in the opening, and wherein the core includes a ferromagnetic material.

Another embodiment of the invention includes a semiconductor device with an inductor having a planar coil portion forming an opening in the center thereof, a coil received in the opening, and wherein the planar coil portion includes an electrically conductive line that encircles the core 2.5 times.

Another embodiment of the invention includes a semiconductor device including an inductor having a planar coil portion forming an opening in the center thereof and a coil received in the opening, and further including first and second inter-metal dielectric layers. The inductor further includes a first connecting leg of an electrically conductive material. The first connecting leg is connected to the planar coil portion. The planar coil portion being formed in the first inter-metal dielectric layer and the first connecting leg being in the second inter-metal dielectric layer.

Another embodiment of the invention includes a semiconductor device having an inductor including a planar coil portion forming an opening in the center thereof and a core received in the opening, and a first connecting leg connected to the planar coil portion, and a second connecting leg connected to the planar coil portion.

Another embodiment of the invention includes a semiconductor device having an inductor including a planar coil portion forming an opening in the center thereof and a core received in the opening, and a first connecting leg connected to the planar portion, and a second connecting leg connected to the planar portion, and an electrically conductive bump connected to the second connecting leg.

Another embodiment of the invention includes a semiconductor device including an inductor having a planar coil portion forming an opening in the center thereof and a core received in the opening, and further including first and second inter-metal dielectric layers. The inductor further includes a first connecting leg of an electrically conductive material. The first connecting leg is connected to the planar coil portion. The planar coil portion is in the first inter-metal dielectric layer and the first connecting leg being in the second inter-metal dielectric layer, and an electrically conductive plug extending from the first connecting leg to the planar coil portion.

Another embodiment of the invention includes a semiconductor device having an inductor including a planar coil portion forming an opening in the center thereof and a core received in the opening, and a first connecting leg connected to the planar portion, and a second connecting leg connected to the planar portion, and an electrically conductive line connected to the second connecting leg.

Another embodiment of the invention includes a semiconductor device having an inductor including a planar coil portion forming an opening in the center thereof and a core received in the opening, and a first inter-metal dielectric layer adjacent a second inter-metal dielectric layer adjacent a third inter-metal dielectric layer, and wherein the core extends through the first, second and third inter-metal dielectric layers.

Another embodiment of the invention includes a semiconductor device having an inductor including a planar coil portion forming an opening in the center thereof and a core received in the opening and extending above and below the planar coil portion, and a inter-metal dielectric layer and at least a portion of the core being received in the inter-metal dielectric layer.

Another embodiment of the invention includes a semiconductor device having an inductor including a planar coil portion forming an opening in the center thereof and a core received in the opening and extending above and below the coil portion, a first and second inter-metal dielectric layer, and the inductor further including a first connecting leg including an electrically conductive material, and wherein the first connecting leg is connected to the planar coil portion, and wherein the planar coil portion is in the first inter-metal dielectric layer and the first connecting leg is in the second inter-metal dielectric layer, and the inductor further including a second connecting leg connected to the planar coil portion, an electrically conductive bump connected to the second connecting leg, and further including an upper dielectric layer, and wherein the planar coil portion is positioned in the upper dielectric layer, the electrically conductive bump positioned over the upper dielectric layer, the core having an upper surface above the upper dielectric layer, and the electrically conductive bump having an upper surface above the upper surface of the core.

Another embodiment of the invention includes a semiconductor device having an inductor including a planar coil portion forming an opening in the center thereof and a core received in the opening and extending above and below the planar coil portion, and wherein the core has a substantially square cross-section.

Another embodiment of the invention includes a semiconductor device having an inductor including a planar coil portion forming an opening in the center thereof and a core received in the opening and extending above and below the planar coil portion, and the core having a substantially square cross-section, and the planar coil portion including a plurality of straight segments connected together to encircle the core.

These and other objects, features and advantages of the present invention will become apparent from the following brief description of the drawings, detailed description of the preferred embodiments, and appended claims and drawings.

### BRIEF DESCRIPTION OF THE DRAWINGS

FIG. 1 is a plan view of a semiconductor device including an inductor and magnetic core according to one embodiment of the present invention; and

FIG. 2 is a sectional view of a semiconductor device including an inductor and magnetic core according to one embodiment of the present invention.

### DETAILED DESCRIPTION OF THE PREFERRED EMBODIMENTS

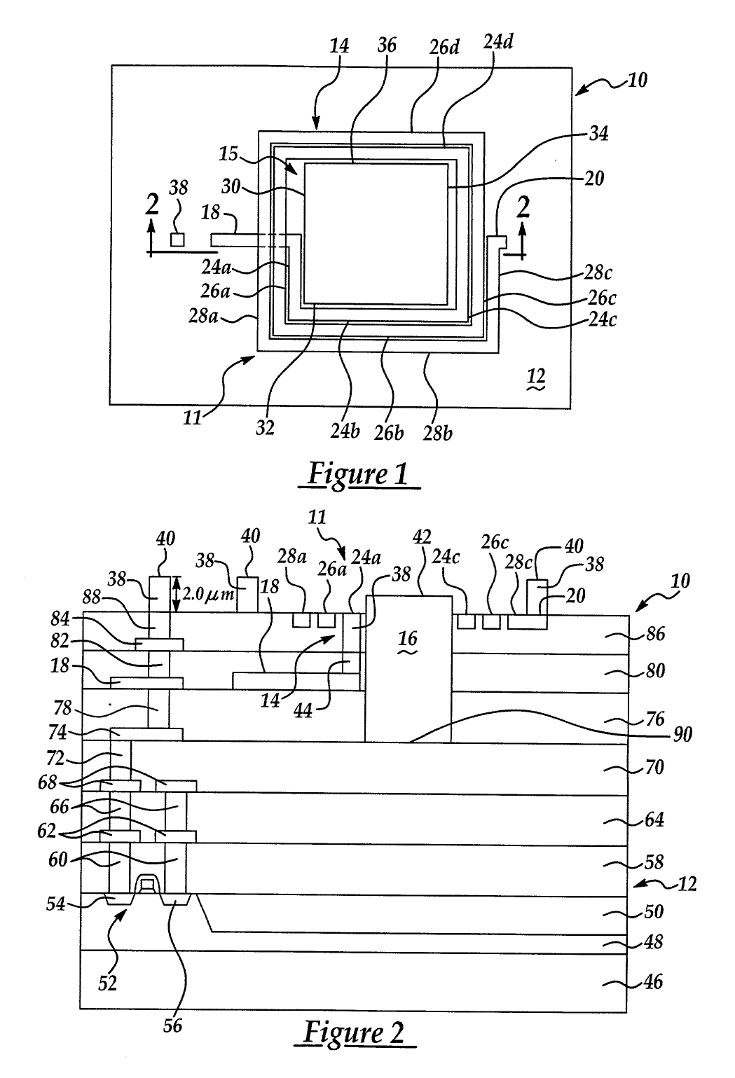

FIG. 1 is plan view of a semiconductor device 10 having a body portion 12 and an inductor 11 formed therein. The inductor 11 includes a planar coil portion 14 forming a central opening (or window) 15 in the center of the coil. The inductor 11 also includes a core 16 positioned in the opening 15 in the planar coil portion 14. In a preferred embodiment the core 16 is a magnetic material, preferably a ferromagnetic material. The core 16 may have a variety of configurations, but preferably as shown in FIG. 1, has a square or rectangular shaped cross-section. The core 16 includes first, second, third, and fourth sides 30, 32, 34, 36. The inductor 11 includes a first connecting leg 18 that is connected to the planar coil portion 14 at the start of a first coil segment 24a that is closest to the first side 30 of the core 16. The first coil segment 24a starts about midway along the first side 30 of the core 16. The first coil segment 24a connects to a second coil segment 24b that runs closest to and along the length of the second side 32 of the core 16. The second coil segment 24b is connected to an a third coil segment 24c that runs closest to and along the third side 34 of the core 16. The third coil segment 24c is connected to a fourth coil segment 24d that runs closest to and along the fourth side 36 of the core 16.

The fourth coil segment 24d is connected to a fifth coil segment 26a that runs nearest the first coil segment 24a and along in the first side 30 of a core 16. The fifth coil segment 26a is connected to a sixth coil segment 26b that runs nearest and along the second coil segment 24b. The sixth coil segment 26b is connected to a seventh coil segment 26c that runs nearest and along in the third coil segment 24c. The seventh coil segment 26c is connected to an eighth coil segment 26d that runs nearest and along the fourth coil segment 24d.

The eighth coil segment 26d is connected to a ninth coil segment 28a that is nearest and runs along the fifth coil segment 26a. The ninth coil segment 28a is connected to a tenth coil segment 28b that is nearest and runs along the sixth coil segment 26b. The tenth coil segment 28c is connected to an eleventh coil segment that is nearest and runs along the seventh coil segment 26c and terminates at about the midway point of the seventh coil segment 26c. A second connecting leg 20 may be attached to the eleventh coil segment 28c. The first through eleventh coil segments of the planar coil portion 14 are formed all in the same plane and provide 2.5 turns around the core 16. An electrically conductive bump (preferably a solder bump) or an electrically conductive line (not shown) may be attached to the second connecting leg 20 as will be described hereafter in FIG. 2. Other electrically conductive bumps or electrically conductive lines 38 may be provided on the body portion 12 of the semiconductor device 10.

FIG. 2 is a sectional view of one embodiment of the present invention which includes a semiconductor device 10 having an inductor 11. The semiconductor device 10 includes a body portion 12 which may include a silicon based substrate 46 into which a N or P-well is formed as well as a shallow trench isolation region 50. A discrete device 52 may be formed in portions of the silicon based substrate 46. An interlayer dielectric 58 may be formed over the discrete devices 52 and electrically conductive plugs 60 may be formed through the interlayer dielectric 58 connecting to active regions 54, 56 of the discrete device 52. A first layer metallization 62 may be formed over the interlayer dielectric 58. A first inter-metal dielectric 64 may be formed over the first metallization layer 62 and electrically conductive plugs 66 may be formed through the first inter-metal dielectric layer 64 down to the first metallization layer 62. A second inter-metal dielectric 68 may be formed over the first inter-metal dielectric 64. A second inter-metal dielectric 70 may be formed over the second metallization 68 and a plug 72 formed through the second inter-metal dielectric 70 down to a second metallization layer 68. A third metallization layer 74 may be formed over the second inter-metal dielectric layer 70. A third inter-metal dielectric 76 may be formed over the third metallization 76 and a plug 78 formed through the third inter-metal dielectric 76 down to the third metallization 74. A fourth metallization 18 may be formed over the third inter-metal dielectric layer 76. A fourth inter-metal dielectric layer 80 may be formed over the third metallization layer 18 and plugs 82, 44 may be formed through the fourth inter-metal dielectric layer 80 down to the fourth metallization layer 18. A fifth metallization layer 84 may be provided over the fourth inter-metal dielectric layer 80. A fifth inter-metal dielectric layer 86 may be formed over the fifth metallization 84 and a plug 88 formed through the fifth inter-metal dielectric layer 86 down to the fifth metallization layer 84. The plug 88 may be connected to electrically conductive bump or electrically conductive layer 38 on top of the fifth inter-metal dielectric layer 86.

The inductor 11 includes the fourth metallization layer 18 that is connected through plug 44 to the first coil segment 24a of the planar coil portion 14. The first through eleventh coil segments of the coil portion 14 are formed in the fifth inter-metal dielectric layer 86. The planar coil portion 14 may be formed by any of a variety of methods known to those skilled in the art including electroplating or screen printing an electrically conductive material such as copper into openings formed in an inter-metal dielectric layer or on top of an inter-metal dielectric layer or passivation layer. Preferably the core 16 extends above the planar coil portion 14 and has an upper surface 42 which rises above the upper surfaces of each of the coil segments of the planar coil portion 14. The core 16 may also extend substantially below the planar coil portion 14, preferably extending through the fifth, fourth, and third inter-metal dielectric layers 86, 80 and 76 and includes a lower surface 90 that rest over the second inter-metal dielectric layer 70. The core 16 may be formed by a electroplated magnetically soft alloys such as permalloy (Ni₈OFe₂O), orthnol (Ni₅OFe₅O), amorphous CoFeCu, supermalloy (NiFeMo), and polymer ferite materials into openings formed in each of the inter-metal dielectric layers as desired. Polyimide filled NiZn and MnZn ferrites may be screen printed into openings formed in each of the inter-metal dielectric layers as desired. Preferably the electrically conductive bumps or electrically conductive lines 38 include an upper surface 40 that is above the upper surface 42 of the core 16.

The inductance increase due to the ferromagnetic core 16 will provide a substantial increase in the Q factor. The die size of the semiconductor device may be deceased due to the replacement of oxide with the ferromagnetic core 16.

What is claimed is:

1. A semiconductor device comprising:
an inductor including a planar coil portion forming an opening in the center thereof and a core received in the opening and extending above and below the planar coil portion.

2. A semiconductor device as set forth in claim 1 wherein the core comprises a magnetic material.

3. A semiconductor device as set forth in claim 1 wherein the core comprises a ferromagnetic material.

4. A semiconductor device wherein the planar coil portion includes an electrically conductive line circles around the core 2.5 times.

5. A semiconductor device as set forth in claim 1 further comprising a first and a second inter-metal dielectric layer, and the inductor further including a first connecting leg comprising an electrically conductive material, and wherein the first connecting leg is connected to the planar coil portion, and wherein the planar coil portion is in the first inter-metal dielectric layer and the first connecting leg is in the second inter-metal dielectric layer.

6. A semiconductor device as set forth in claim 5 wherein the inductor further comprises a second connecting leg connected to the planar coil portion.

7. A semiconductor device as set forth in claim 6 further comprising an electrically conductive bump connected to the second connecting leg.

8. A semiconductor device as set forth in claim 6 further comprising an electrically conductive plug extending from the first connecting leg to the planar coil portion.

9. A semiconductor device as set forth in claim 6 further comprising an electrically conductive line connected to the second connecting leg.

10. A semiconductor device as set forth in claim 1 further comprising a first inter-metal dielectric layer adjacent a second inter-metal dielectric layer adjacent a third inter-metal dielectric layer, and wherein the core extends through the first, second and third inter-metal layers.

11. A semiconductor device as set forth in claim 1 further comprising an inter-metal dielectric layer and at least a portion of the core being received in the inter-metal dielectric layer.

12. A semiconductor device as set forth in claim 7 further comprising an upper dielectric layer, and wherein the planar core portion is positioned in the upper dielectric layer, the electrically conductive bump positioned over the upper dielectric layer, the core having an upper surface above the upper dielectric layer, and the electrically conductive bump having an upper surface above the upper surface of the core.

13. A semiconductor device as set forth in claim 1 wherein the core has a substantially square cross-section.

14. A semiconductor device as set forth in claim 13 wherein the planar coil portion includes a plurality of straight segments connected together to encircled the core.
